(19) United States
(12) Patent Application Publication
(10) Pub. No.: US 2024/0421180 A1
(43) Pub. Date: Dec. 19, 2024

(54) LIGHT EMITTING ELEMENT ARRAY, MASK, AND LIGHT EMITTING ELEMENT MANUFACTURING METHOD

(71) Applicant: Samsung Display Co., LTD., Yongin-si (KR)

(72) Inventors: Myeong Su SO, Yongin-si (KR); Moon Jung AN, Yongin-si (KR); Joo Yeol LEE, Yongin-si (KR)

(21) Appl. No.: 18/657,486

(22) Filed: May 7, 2024

(30) Foreign Application Priority Data
Jun. 14, 2023 (KR) 10-2023-0076065

(51) Int. Cl. H01L 27/15; H01L 25/18

(52) U.S. Cl. CPC H01L 27/156; H01L 25/18

(57) ABSTRACT

A light emitting element array includes: a base substrate; a plurality of light emitting elements on the base substrate; an insulating layer on side surfaces and one surface of each of the plurality of the light emitting elements and having an opening on the one surface; and a plurality of connection electrodes, each of the connection electrodes being at the opening in the one surface of the insulating layer of a corresponding one of the plurality of light emitting elements, the connection electrodes of neighboring light emitting elements of the plurality of light emitting elements have a different sizes, and connection electrodes of the plurality of light emitting elements are arranged on the base substrate in a repeating pattern.

### CROSS-REFERENCE TO RELATED APPLICATION

The present application claims priority to and the benefit of Korean Patent Application No. 10-2023-0076065, filed on Jun. 14, 2023, in the Korean Intellectual Property Office, the entire disclosure of which is incorporated by reference herein.

### BACKGROUND

### 1. Field

The present disclosure relates to a light emitting element array, a mask, and a method of manufacturing a light emitting element.

### 2. Description of the Related Art

Display devices are becoming increasingly important with the development of multimedia. In response to this, various types of display devices, such as organic light emitting displays (OLED) and liquid crystal displays (LCD), are being used.

A device for displaying an image includes a display panel such as an organic light emitting display panel or a liquid crystal display panel. Among them, the light emitting display panel may include a light emitting element. For example, light emitting diodes (LEDs) include organic light emitting diodes (OLEDs) that utilize organic materials as light emitting materials, inorganic light emitting diodes that utilize inorganic materials as light emitting materials, and the like.

### SUMMARY

Aspects and features of embodiments of the present disclosure provide a mask, a light emitting element array, and a method of manufacturing to reduce or minimize the defect at the boundary of the shot when forming a pattern of the mask applied to the connection electrode of the light emitting element.

It is also to provide a light emitting element array that may solve the current distribution problem that may be caused by the difference in size of the connection pattern.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a light emitting element array includes: a base substrate; a plurality of light emitting elements on the base substrate; an insulating layer on side surfaces and one surface of each of the plurality of the light emitting elements and having an opening on the one surface; and a plurality of connection electrodes, each of the connection electrodes being at the opening in the one surface of the insulating layer of a corresponding one of the plurality of light emitting elements, wherein the connection electrodes of neighboring light emitting elements of the plurality of light emitting elements have a different sizes, and wherein connection electrodes of the plurality of light emitting elements are arranged on the base substrate in a repeating pattern.

According to one or more embodiments, a diameter of the opening in the insulating layer is proportional to a diameter of a corresponding one of the connection electrodes.

According to one or more embodiments, the plurality of light emitting elements includes a first light emitting element and a second light emitting element adjacent to the first light emitting element, and a diameter of the connection electrode of the first light emitting element is smaller than a diameter of the connection electrode of the second light emitting element.

According to one or more embodiments, a diameter of a first opening in the insulating layer of the first light emitting element is smaller than a diameter of a second opening of the insulating layer of the second light emitting element.

According to one or more embodiments, the diameter of the connection electrode of the first light emitting element is different from diameters of the connection electrodes of light emitting elements of the plurality of light emitting elements located at an upper side, a lower side, a left side, and a right side of the first light emitting element.

According to one or more embodiments, the diameter of the first opening in the insulating layer of the first light emitting element is smaller than diameters of the openings in the insulating layers of the light emitting elements of the plurality of light emitting elements located at an upper side, a lower side, a left side, and a right side of the first light emitting element.

According to one or more embodiments, diameters of the connection electrodes of the plurality of light emitting elements in the light emitting element array gradually increase or decrease in a first direction and a second direction.

According to one or more embodiments, the base substrate is a sapphire substrate (Al2O3) or a silicon wafer including silicon.

According to one or more embodiments, a mask includes: a mask sheet on the base substrate when manufacturing the connection electrode; and a plurality of mask patterns in the mask sheet, having a light transmittance different from that of the mask sheet, and corresponding to connection electrodes on the base substrate, wherein the plurality of mask patterns are regular polygonal patterns over the mask sheet, and wherein the plurality of mask patterns have different sizes from neighboring mask patterns.

According to one or more embodiments, the plurality of mask patterns includes a first pattern and a second pattern adjacent to the first pattern, wherein the first pattern is smaller than the second pattern.

According to one or more embodiments, the first pattern has a different size from patterns located at an upper side, a lower side, a left side, and a right side of the first pattern.

According to one or more embodiments, a size of the plurality of mask patterns decreases from a center to a side.

According to one or more embodiments, the plurality of mask patterns are light-transmitting areas, and an outer portion of the mask sheet where the plurality of mask patterns are not located is a light-blocking area.

According to one or more embodiments, a method of manufacturing a light emitting element including: forming a plurality of semiconductor material layers on a base substrate; etching the plurality of semiconductor material layers to form a plurality of light emitting elements; forming an insulating layer around sides and one end of each of the plurality of light emitting elements; forming an opening in the insulating layer of the one end of each of the plurality of light emitting elements; and forming a connection electrode using a mask at the one end of each of the plurality of light emitting elements having the opening, wherein the mask includes a plurality of mask patterns corresponding to connection electrodes of the plurality of light emitting elements, and wherein the plurality of mask patterns have polygonal shapes and has different sizes from neighboring mask patterns.

According to one or more embodiments, the plurality of mask patterns includes a first pattern and a second pattern adjacent to the first pattern, and wherein the first pattern is smaller than the second pattern.

According to one or more embodiments, the first pattern has a different size from patterns located at an upper side, a lower side, a left side, and a right side of the first pattern.

According to one or more embodiments, a size of the plurality of mask patterns decreases from a center to a side.

According to one or more embodiments, a diameter of the opening in the insulating layer of is proportional to a diameter of the connection electrode in each of the plurality of light emitting elements.

According to one or more embodiments, connection electrodes formed by the plurality of mask patterns have different sizes from connection electrodes of adjacent light emitting elements of the plurality of light emitting elements.

According to one or more embodiments, diameters of the connection electrodes of the plurality of light emitting elements gradually increase or decrease in a first direction and a second direction.

In a display device according to one or more embodiments, when forming a pattern of the mask applied to the connection electrode of the light emitting element, a defect at the boundary of a shot may be reduced or minimized.

In addition, the current distribution problem that may be caused by differences in the size of the connection pattern may be solved.

It is possible to reduce or prevent the phenomenon that the light emitting element is biased toward (e.g., located too close to) the edge of the pixel electrode on the pixel electrode, such that the light emitting element falls, by making the diameter of the light emitting element smaller than the cross-sectional diameter of the pixel electrode.

In this way, an opening defined by an insulating layer may be made proportional to the size of the connecting electrode, thereby improving the problem of unbalanced current distribution due to the difference in size of the connecting electrode.

However, the effects, aspects, and features of embodiments of the present disclosure are not limited to the aforementioned effects, aspects, and features, and various other effects, aspects, and features, are included in the present disclosure.

### BRIEF DESCRIPTION OF THE DRAWINGS

FIG. 1 is a plan view of a light emitting element array, according to one or more embodiments.

FIG. 2 is a cross sectional view taken along the line A-A′ of FIG. 1.

FIG. 3 is an enlarged view of an area B of FIG. 2.

FIG. 4 is a plan view illustrating an exposure method used in a light emitting element manufacturing process.

FIG. 5 is a plan view illustrating an overlapping area of shots in a light emitting element manufacturing process.

FIG. 6 is a plan view illustrating an overlapping area of misaligned shots.

FIG. 7 is a plan view illustrating a mask according to one or more embodiments.

FIG. 8 is a plan view illustrating an overlapping area of shots in a light emitting element manufacturing process using the mask of FIG. 7.

FIG. 9 is a plan view illustrating an overlapping area of a misaligned shot using the mask of FIG. 7.

FIG. 10 is a plan view of a light emitting element array according to one or more embodiments.

FIG. 11 is a cross sectional view taken along the line C-C′ of FIG. 10.

FIG. 12 is a plan view illustrating a mask according to one or more embodiments.

FIG. 13 is a plan view illustrating an overlapping area of shots in a light emitting element manufacturing process using the mask of FIG. 12.

FIG. 14 is a plan view illustrating an overlapping area of a misaligned shot using the mask of FIG. 7.

FIGS. 15 to 19 are drawings to illustrate a manufacturing method of a light emitting element array according to one or more embodiments.

FIGS. 20 and 21 are drawings to illustrate a method of transferring a light emitting element array to a display board.

### DETAILED DESCRIPTION

One or more embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B, or A or B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and/or B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the present disclosure will be described in detail with reference to the accompanying drawings.

In the manufacture of light emitting elements, a plurality of masks may be performed sequentially on the growth substrate.

The mask process may include the following steps.

First, an insulating film or a metal film is fully deposited on the substrate by chemical vapor deposition (CVD) or sputtering.

Then, the surface of the deposited film formed on the substrate is cleaned and coated with a photo resist, and the desired pattern shape is obtained by an exposure and development process using the mask.

Then, the deposited film is etched to form the desired pattern using the patterned photoresist as the mask, and then the patterned photoresist is removed to complete the mask process.

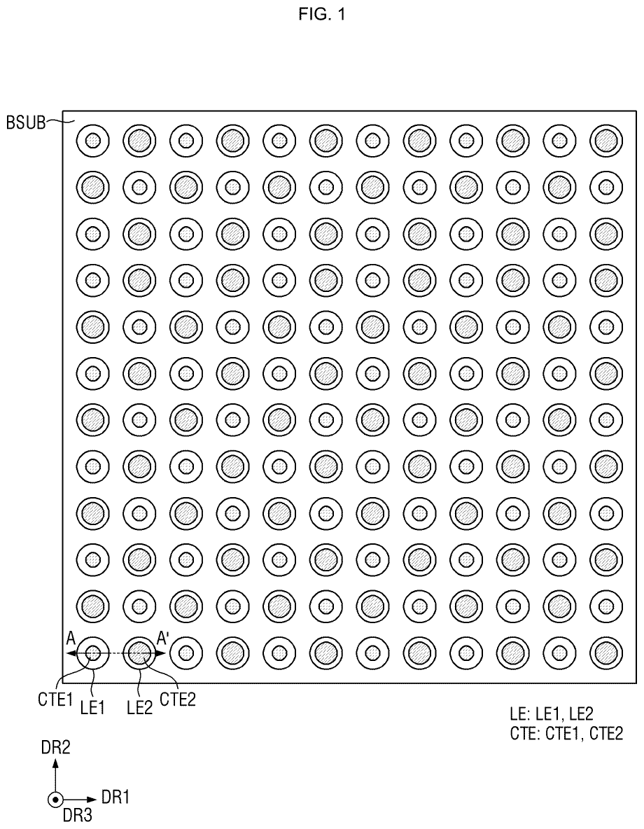

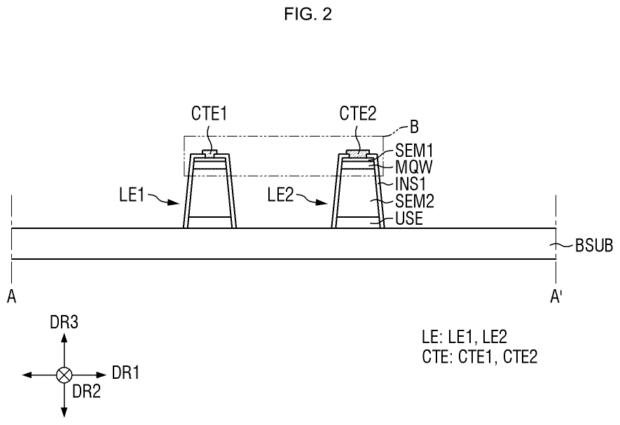

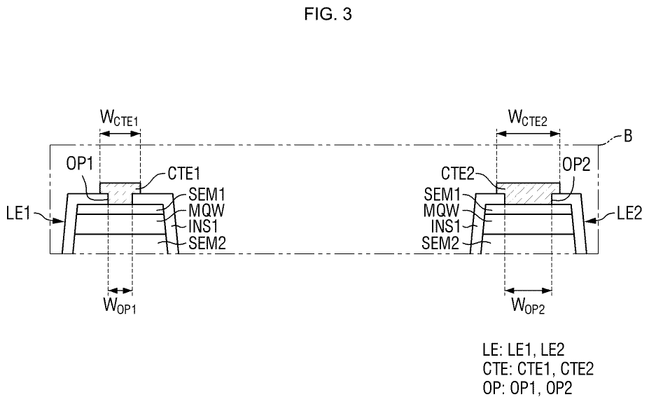

FIG. 1 is a plan view of a light emitting element array, according to one or more embodiments. FIG. 2 is a cross sectional view taken along the line A-A′ of FIG. 1. FIG. 3 is an enlarged view of a region B of FIG. 2.

In FIGS. 1 and 2, a light emitting element LE according to one or more embodiments is described mainly as a micro light emitting diode display device (e.g., a micro or nano light emitting diode display device) including an ultra-compact light emitting diode (e.g., a micro or nano light emitting diode) but the present disclosure is not limited thereto.

In addition, referring to FIG. 1, a plurality of light emitting elements LE are arranged in the first direction DR1 and the second direction DR2 on a base substrate BSUB according to one or more embodiments. The plurality of light emitting elements LE are spaced from each other at a uniform interval. In other words, a distance between a pair of adjacent light emitting elements LE is the same as a distance between each other pair of two adjacent light emitting elements LE.

The base substrate BSUB may have a rectangular planar shape. However, the planar shape of the base substrate BSUB is not limited thereto, and may have a polygonal, circular, elliptical, or irregular planar shape other than the rectangular.

The base substrate BSUB may be a sapphire substrate Al2O3 or a silicon wafer including silicon. However, it is not limited thereto, and in one or more embodiments, a case where the base substrate BSUB is the sapphire substrate will be described as an example.

The light emitting element LE may be a vertical light emitting diode element extending in the third direction DR3. That is, the length of the light emitting element LE in the third direction DR3 may be longer than that in the horizontal direction (e.g., the first direction DR1 and/or the second direction DR2). The length in the horizontal direction refers to the length of the first direction DR1 or the length of the second direction DR2.

A connection electrode CTE is disposed on the upper surface of the light emitting element LE.

The connection electrode CTE of a light emitting element LE have a different size than the connection electrode CTE of a neighboring light emitting element LE.

The connecting electrode CTE disposed on a light emitting element LE has a different diameter than the connecting electrodes CTE on light emitting elements that are at upper, lower, left, and right sides of the light emitting element LE.

More specifically, referring to FIGS. 2 and 3, the light emitting element LE may be a micro light emitting diode element. The light emitting element LE may include a third semiconductor layer USE, a second semiconductor layer SEM2, an active layer MQW, a first semiconductor layer SEM1, an insulating layer INS1, and a connecting electrode CTE arranged in the thickness direction of the base substrate BSUB, that is, in the third direction DR3. The third semiconductor layer USE, the second semiconductor layer SEM2, the active layer MQW, and the first semiconductor layer SEM1 may be stacked sequentially in the third direction DR3.

The light emitting element LE may have a cylindrical shape, a disk shape, or a rod shape with a diameter longer than a height. However, the light emitting element LE is not limited thereto, and the light emitting element LE may have a shape such as a rod, a wire, a tube, or a polygonal column shape such as a regular hexahedron, a rectangular parallelepiped, or hexagonal prism or a shape extending in one direction but having a partially inclined outer surface.

The third semiconductor layer USE may be disposed on the base substrate BSUB. The third semiconductor layer USE may be undoped.

The second semiconductor layer SEM2 may be doped with a second conductivity type dopant such as Si, Ge, and/or Sn. For example, the second semiconductor layer SEM2 may be n-GaN doped with n-type Si. The thickness of the second semiconductor layer SEM2 may be approximately 500 nm to 1 μm.

The active layer MQW may emit light by combining electron-hole pairs according to electrical signals applied through the first semiconductor layer SEM1 and the second semiconductor layer SEM2. The active layer MQW may emit first light having a central wavelength range of 450 nm to 495 nm, that is, light in a blue wavelength band.

The active layer MQW may include a single or multiple quantum well structure. If the active layer includes a material with a multi-quantum well structure, it may be a stacked structure with a plurality of well layers and a barrier layer alternating with each other. In this case, the well layer may be formed of InGaN and the barrier layer may be formed of GaN and/or AlGaN, but is not limited thereto. The thickness of the well layer may be approximately 1 to 4 nm, and the thickness of the barrier layer may be 3 to 10 nm.

The active layer MQW may have a structure in which a semiconductor material having a large band gap energy and a semiconductor material having a small band gap energy are alternately stacked with each other and may include other Group III to Group V semiconductor materials depending on the wavelength band of the emitted light. The light emitted from the active layer MQW is not limited to the first light (e.g., light in the blue wavelength band) and may emit second light (e.g., light in the green wavelength band) or third light (e.g., light in the red wavelength band) in some cases.

The first semiconductor layer SEM1 may be doped with a first conductivity type dopant such as Mg, Zn, Ca, Se, and/or Ba. For example, the first semiconductor layer SEM1 may be p-GaN doped with p-type Mg. The thickness of the first semiconductor layer SEM1 may be approximately 30 to 200 nm.

In one or more embodiments, a superlattice layer may be disposed between the second semiconductor layer SEM2 and the active layer MQW. The superlattice layer may be a layer to relieve stress between the second semiconductor layer SEM2 and the active layer MQW. For example, the superlattice layer may be formed of InGaN and/or GaN. A thickness of the superlattice layer may be approximately 50 to 200 nm. The superlattice layer may be omitted.

In one or more embodiments, an electron blocking layer may be further disposed between the first semiconductor layer SEM1 and the active layer MQW. The electron blocking layer may be a layer for suppressing or preventing too many electrons from flowing into the active layer MQW. For example, the electron blocking layer may be p-AlGaN doped with p-type Mg. The thickness of the electron blocking layer may be approximately 10 to 50 nm. The electron blocking layer may be omitted.

A first insulating layer INS1 may be around (e.g., may surround) side surfaces and an upper surface of the light emitting element LE, for example, outer peripheral or circumferential surfaces of the light emitting element LE. The first insulating layer INS1 may insulate the light emitting elements LE from the outside. The first insulating layer INS1 may be directly disposed on outer surfaces (e.g., outer peripheral or circumferential surfaces) of the third semiconductor layer USE, the second semiconductor layer SEM2, the active layer MQW, and the first semiconductor layer SEM1 to be around (e.g., to surround) them. In one or more embodiments, the first insulating layer INS1 may be around (e.g., may surround) the entire outer surfaces (e.g., outer peripheral or circumferential surfaces) of the third semiconductor layer USE, the second semiconductor layer SEM2, the active layer MQW, and the first semiconductor layer SEM1.

The first insulating layer INS1 is formed to expose one end of the third semiconductor layer USEM of the light emitting element LE and cover (e.g., partially cover) the upper surface of the first semiconductor layer SEM1 of the light emitting element LE. The insulating layer INS1 exposes at least a portion of the upper surface of the first semiconductor layer SEM1 through an opening OP.

The first insulating layer INS1 may be disposed to be around (e.g., to surround) the light emitting elements LE. The first insulating layer INS1 may include an inorganic insulating material such as silicon oxide (SiOx), silicon nitride (SiNx), silicon oxynitride (SiOxNy), aluminum oxide (AlxOy), and/or aluminum nitride (AlN), and/or the like. The thickness of the first insulating layer INS1 may be approximately 0.1 μm but is not limited thereto.

The connection electrode CTE may be formed on the openings OP1 and OP2 but may be formed to protrude from the insulating layer INS1 in the third direction.

The connection electrode CTE is connected to the first semiconductor layer SEM1 through the opening OP.

The connection electrode CTE may include a conductive material and serve to transfer a light emitting signal from an external, for example, pixel electrode to the light emitting element LE. The connection electrode CTE may be an Ohmic connection electrode. However, it is not limited thereto, and may be a Schottky connection electrode.

The connection electrode CTE may include at least one of gold (Au), copper (Cu), tin (Sn), silver (Ag), aluminum (Al), and/or titanium (Ti). For example, the connecting layer may include a 9:1 alloy, 8:2 alloy, and/or 7:3 alloy of gold and tin, or may include an alloy of copper, silver, and/or tin (e.g., SAC305).

More specifically, the plurality of light emitting elements may include a first light emitting element LE1 and a second light emitting element LE2 arranged adjacent to the first light emitting element LE1.

A diameter W_{CTE1} of the connection electrode CTE1 disposed on the first light emitting element LE1 may be smaller than a diameter W_{CTE2} of the connection electrode CTE2 disposed on the second light emitting element LE2.

The opening OP defined by the first insulating layer INS1 is proportional to the size of the connection electrode CTE1. For example, a diameter W_{OP1} of the opening OP1 defined by the first insulating layer INS1 of the first light emitting element LE1 may be smaller than a diameter W_{OP2} of the opening OP2 defined by the first insulating layer INS1 of the second light emitting element LE2.

The size of the opening OP defined by the insulating layer INS1 is defined in proportion to the size of the connecting electrode CTE in consideration of the contact resistance generated by the contact area between the first semiconductor layer SEM1 and the connecting electrode CTE. In this way, the problem of unbalanced current distribution due to the difference in size of the connecting electrode CTE may be improved by making the opening OP defined by the insulating layer INS1 proportional to the size of the connecting electrode CTE.

A difference in size between the connection electrodes CTE of the plurality of light emitting elements LE may be set according to the range of the overlapping area and the alignment distribution of the exposure devices.

For example, when forming a pattern of connection electrodes of the light emitting elements LE having a diameter of 10 μm, if the diameter of the overlapping region is 7 μm, the size difference between the light emitting elements LE may be 3 μm.

In another example, when the pattern of the connection electrode of the light emitting elements LE having a diameter of 10 μm is formed, if the diameter of the overlapping region is 7 μm and the alignment distribution of the exposure device is ±2 μm, the size difference between the light emitting elements LE may be 3 μm+2 μm 32 5 μm.

In summary, the size difference between neighboring light emitting elements LE may be equal to or proportional to the diameter of the overlapping area of the shot. Also, the size difference between neighboring light emitting elements LE may take into consideration the diameter of the overlapping area of the shot and the alignment distribution of the exposure device.

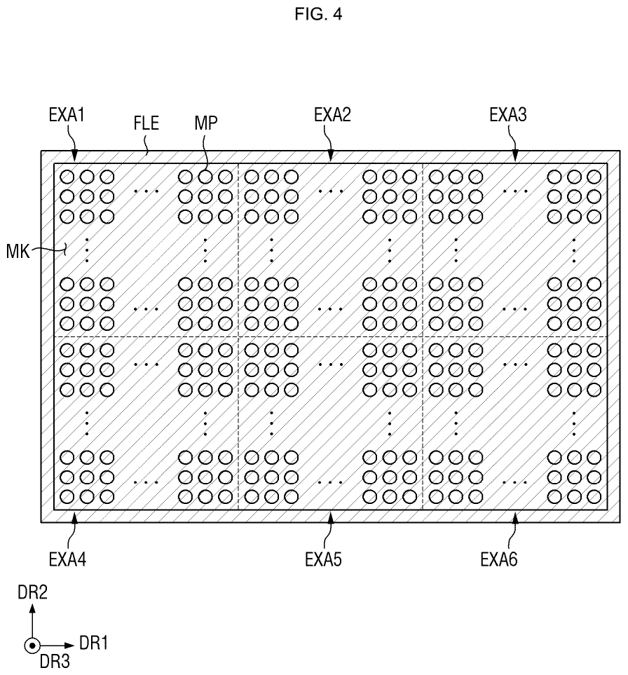

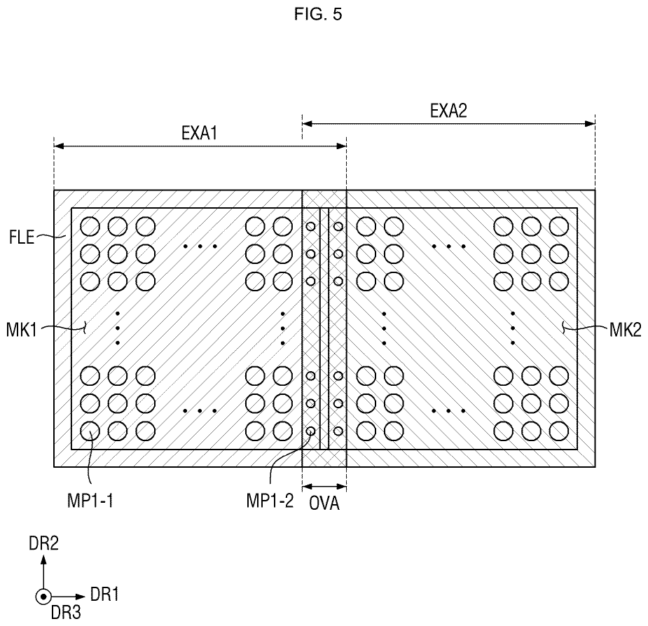

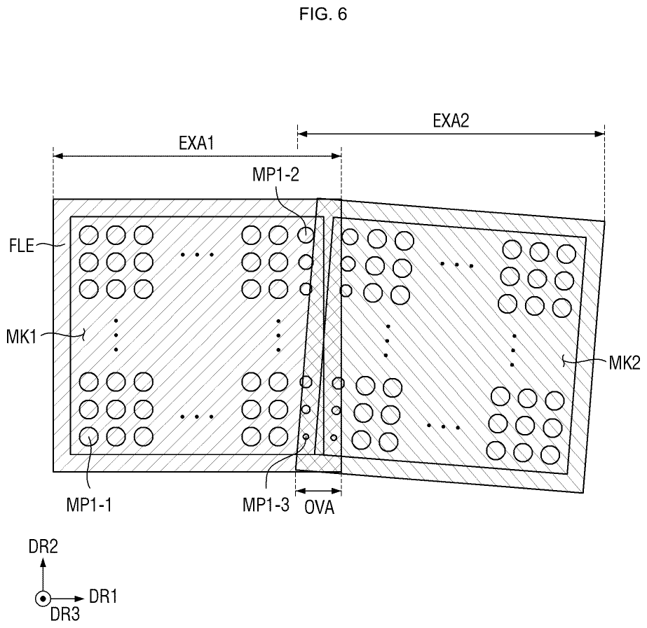

FIG. 4 is a plan view illustrating an exposure method used in a light emitting element manufacturing process. FIG. 5 is a plan view illustrating an overlapping area of shots in a light emitting element manufacturing process. FIG. 6 is a plan view illustrating an overlapping area of misaligned shots.

In one or more embodiments, the connection electrode CTE of the light emitting element LE may be formed by a mask process.

Generally, the mask process is performed by depositing a mask on a substrate, applying a photoresist film, and performing an exposure treatment according to a pattern on the mask. At this time, the mask process may not be completed with single exposure because the production cost increases as the exposure lens becomes larger. Therefore, performing a divisional exposure may be desirable.

In one or more embodiments, the entire surface to be exposed on the substrate is called a field, and a certain area where a suitable pattern (e.g., a predetermined pattern) is transferred with single exposure through a reticle is called a shot.

Referring to FIG. 4, a field FLE may include a plurality of shots EXA1, EXA2, EXA3, EXA4, EXA5, and EXA6. The size of the mask MK may be the same as the size of the shot.

Referring to FIG. 5, when the mask MK is repeatedly exposed to the field FLE, an overlapping area OVA in which neighboring shots EXA1 and EXA2 overlap each other may occur. Here, the mask may be a negative photoresist mask. A photoresist PR is a chemical substance whose characteristics change in response to light (e.g., photosensitization). Negative photoresist has a feature that a portion not exposed to light is dissolved. Accordingly, the mask for negative photoresist blocks light in a portion where a pattern is to be formed.

An abnormal pattern MP1-2 having a different size from the normal pattern MP1-1 may occur in the overlapping area OVA.

The actual shots may not be accurately aligned because distortions such as transition, rotation, and twisting occur. In this case, a stitch defect occurs on the screen due to the discontinuity between the two shots.

Referring to FIG. 6, when the masks of the neighboring shots EXA1 and EXA2 are misaligned with each other, the size difference between the normal pattern MP1-1 and the abnormal pattern MP1-3 occurring in the overlapping area OVA may be further intensified.

In this way, a rapid change in luminance may occur in the light emitting element array formed by the abnormal pattern generated in the overlapping area of the shot.

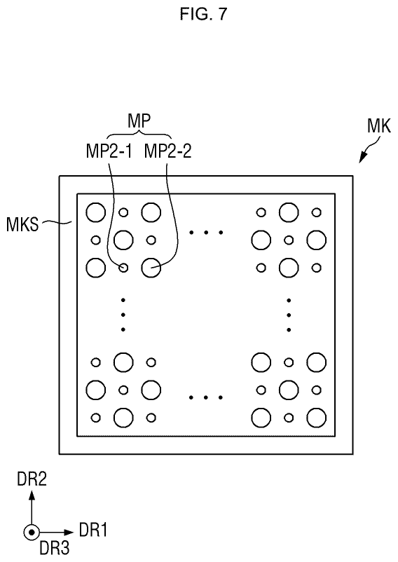

FIG. 7 is a plan view illustrating a mask according to one or more embodiments.

The mask of FIG. 7 may be a mask for forming the connection electrode CTE of the light emitting element LE described with reference to FIGS. 1 to 3.

The mask MK may include a mask sheet MKS and a plurality of mask patterns MP. The mask may be the negative photoresist mask but is not limited thereto.

The mask sheet MKS and the plurality of mask patterns MP have different light transmittances.

When the mask MK is disposed on the base substrate, the mask pattern MP is disposed in an area where the connection electrode is formed on the light emitting element.

The plurality of mask patterns MP may be circular or polygonal patterns that repeat throughout the mask sheet MKS. The polygon may be a square, a rectangle, or a hexagon, but is not limited thereto.

The size of the mask pattern MP is different from that of neighboring mask patterns MP.

The plurality of mask patterns MP includes a first pattern MP2-1 and a second pattern MP2-2 adjacent to the first pattern MP2-1, and the first pattern MP2-1 may be smaller than the second pattern MP2-2. The plurality of mask patterns MP may be regularly arranged throughout the mask sheet MKS.

The first pattern MP2-1 has a size different from patterns disposed on the upper, lower, left, and right sides of the first pattern MP2-1. For example, the first pattern MP2-1 may be formed smaller than patterns disposed in the upper, lower, left, and right directions.

The plurality of mask patterns MP may be a light transmission area, and an outer portion of the mask sheet MKS in which the plurality of mask patterns MP are not disposed may be a light blocking area.

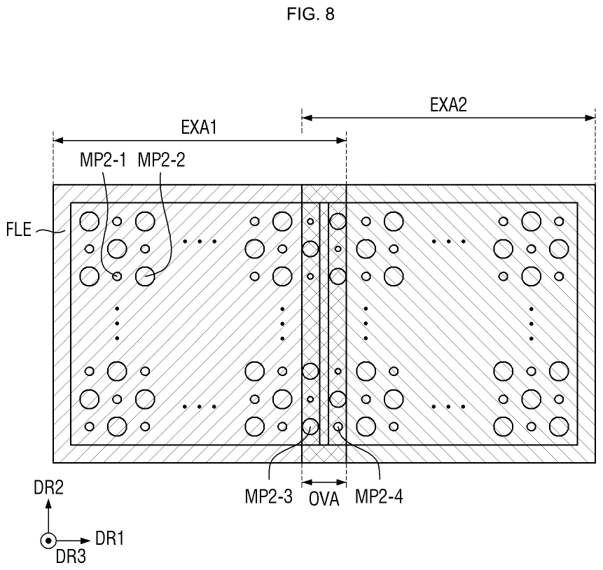

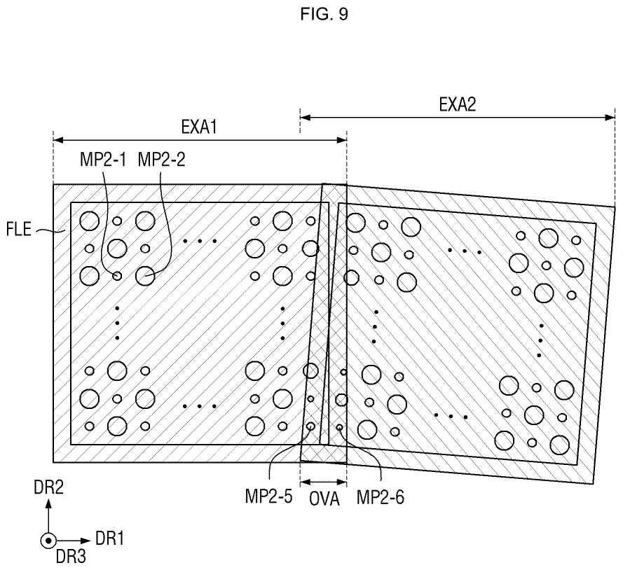

FIG. 8 is a plan view illustrating an overlapping area of shots in a light emitting element manufacturing process using the mask of FIG. 7. FIG. 9 is a plan view illustrating an overlapping area of a misaligned shot using the mask of FIG. 7.

Referring to FIG. 8, a plurality of shots EXA1 and EXA2 may be included. The size of the mask MK may be the same as the size of the shot.

Referring to FIG. 8, when the mask MK is repeatedly exposed to the field FLE, an overlapping area OVA in which neighboring shots EXA1 and EXA2 overlap each other may occur.

As some patterns become smaller, a margin is created for adjacent shots in the overlapping area OVA. Accordingly, patterns MP2-3 and MP2-4 having substantially the same size as or substantially the same size as the normal patterns MP2-1 and MP2-2 may be formed in the overlapping area OVA.

Referring to FIG. 9, when the masks of neighboring shots EXA1 and EXA2 are misaligned with each other, the size difference between the normal pattern MP2-1, MP2-2 and the abnormal pattern MP2-5, MP2-6 that occurs in the overlap area (OVA) may be further intensified. The normal patterns MP2-1 and MP2-2 may include the first pattern MP2-1 and the second pattern MP2-2.

In one or more embodiments, in the case of the abnormal pattern MP2-6, when the shots do not overlap, the pattern MP2-6 having the same size as the second pattern MP2-2 may be formed in the overlap area OVA with a smaller than normal size due to exposure by the first shot EXA1 and the second shot EXA2.

Nevertheless, when viewed in the entire field FLE, a gradual change rather than a sudden change may be recognized even in the overlapping area OVA due to the repetition of large and small patterns.

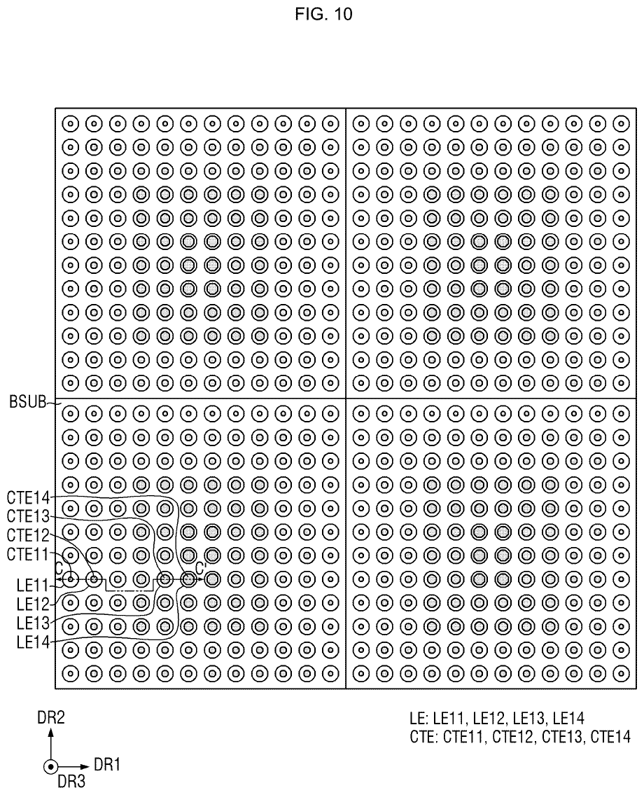

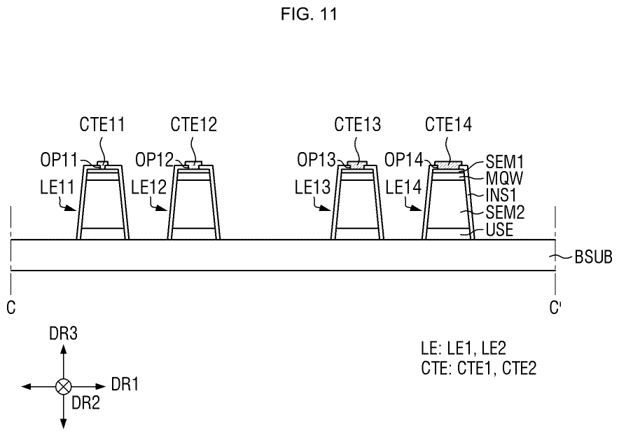

FIG. 10 is a plan view of a light emitting element array according to one or more embodiments. FIG. 11 is a cross sectional view taken along the line C-C′ of FIG. 10.

Referring to FIGS. 10 and 11, the plurality of light emitting elements LE are arranged in the first direction DR1 and the second direction DR2 on the base substrate BSUB according to one or more embodiments. The plurality of light emitting elements LE are spaced from each other at equal intervals. The plurality of light emitting elements may include a first light emitting element LE11, a second light emitting element LE12, a third light emitting element LE13, and a fourth light emitting element LE14. The first light emitting element LE11 and the second light emitting element LE12 may be adjacent to each other, and the third light emitting element LE13 and the fourth light emitting element LE14 may be adjacent to each other.

The connection electrode CTE is disposed on the plurality of light emitting elements LE.

The connection electrode CTE is formed in a different size from the connection electrode CTE of the neighboring light emitting element LE. For example, the connection electrode CTE11 of the first light emitting element LE11 and the connection electrode CTE12 of the second light emitting element LE12 adjacent to the first light emitting element LE11 are formed in different sizes.

A diameter of the connection electrode CTE11 disposed on the first light emitting element LE11 may be smaller than a diameter of the connection electrode CTE12 disposed on the second light emitting element LE12.

Also, the opening OP defined by the first insulating layer INS1 is proportional to the size of the connection electrode CTE. For example, a diameter of the opening OP11 defined by the first insulating layer INS1 of the first light emitting element LE11 may be smaller than a diameter of the opening OP12 defined by the first insulating layer INS1 of the second light emitting element LE12.

The size of the opening OP defined by the insulating layer INS1 is defined in proportion to the size of the connection electrode CTE in consideration of the contact resistance generated by the contact area between the first semiconductor layer SEM1 and the connection electrode CTE. In this way, the problem of unbalanced current distribution due to the difference in size of the connecting electrode CTE may be improved by making the opening OP defined by the insulating layer INS1 proportional to the size of the connecting electrode CTE.

In summary, a size difference between neighboring light emitting elements LE may be equal to or proportional to the diameter of the overlapping area of the shot. In addition, the size difference between neighboring light emitting elements LE may consider the diameter of the overlapping area of the shot and the alignment distribution of the exposure device.

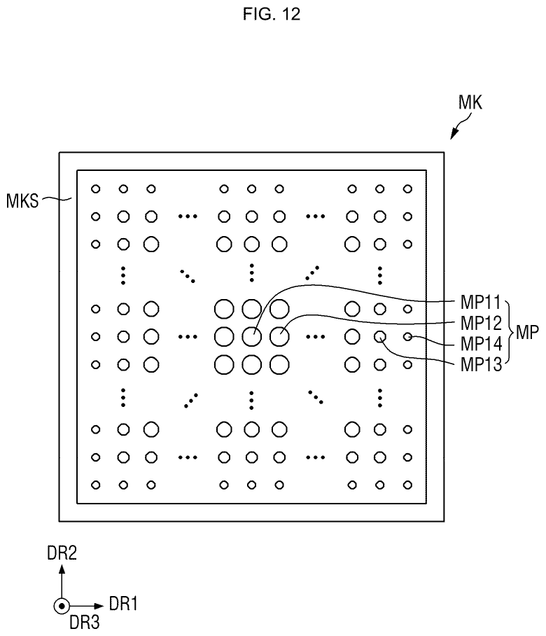

FIG. 12 is a plan view to illustrate a mask according to one or more embodiments.

The mask of FIG. 12 may be a mask for forming the connection electrode CTE of the light emitting element LE described with reference to FIGS. 10 to 13.

The mask MK may include the mask sheet MKS and a plurality of mask patterns MP. The mask may be the negative photoresist mask but is not limited thereto.

The mask sheet MKS and the plurality of mask patterns MP have different light transmittances.

When the mask MK is disposed on the base substrate, the mask pattern MP is disposed in an area where the connection electrode is formed on the light emitting element.

The size of the plurality of mask patterns MP may gradually decrease from the center of the mask sheet MKS to the periphery of the mask sheet MKS. The plurality of mask patterns MP may include a first pattern MP11 in the center of the mask MK, a second pattern MP12 adjacent to the first pattern MP11, a fourth pattern MP14 on the periphery of the mask MK, and a third pattern MP13 adjacent to the fourth pattern MP14. The second pattern MP12 is disposed closer to the periphery than the first pattern MP11. The fourth pattern MP14 is disposed closer to the periphery than the third pattern MP13. Thus, the first pattern MP11, the second pattern MP12, the third pattern MP13, and the fourth pattern MP14 may be disposed in the following order from the center of the mask MK. Accordingly, the sizes of the first pattern MP11, the second pattern MP12, the third pattern MP13, and the fourth pattern MP14 may be progressively reduce in size from the center of the mask MK.

The plurality of mask patterns MP may be arranged in a regular pattern throughout the mask sheet MKS.

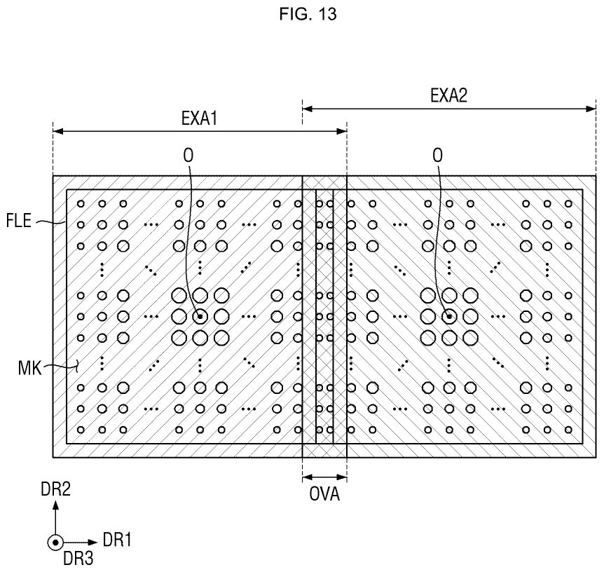

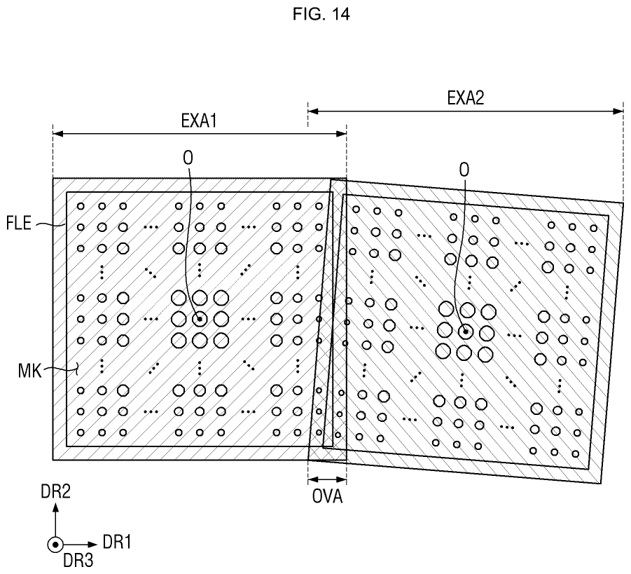

FIG. 13 is a plan view illustrating an overlapping area of shots in a light emitting element manufacturing process using the mask of FIG. 12. FIG. 14 is a plan view illustrating an overlapping area of a misaligned shot using the mask of FIG. 7.

Referring to FIG. 13, a plurality of shots EXA1 and EXA2 may be included. The size of the mask MK may be the same as the size of the shot.

Referring to FIG. 13, when the mask MK is repeatedly exposed to the field FLE, the overlapping area OVA may occur in which neighboring shots EXA1 and EXA2 overlap each other.

In the overlapping area OVA, an overlapping phenomenon in which the size of the normal pattern MP is formed smaller may occur. Nevertheless, because the mask pattern MP gradually decreases from the center of the mask MK to the periphery, the overlapping area OVA may be perceived as a gradual change rather than a sudden change when viewed from the entire field FLE.

Referring to FIG. 14, when the masks of the neighboring shots EXA1 and EXA2 are misaligned with each other, an abnormal pattern that is smaller than the non-overlapping pattern may occur in the overlapping area OVA.

Nonetheless, because the pattern gradually decreases from the center of the mask O to the periphery of the entire field FLE, the gradual change rather than the sudden change may be recognized even in the overlapping area. Accordingly, in the case of the light emitting element array having the connection electrode manufactured by the mask MK, a gradual change in brightness rather than the sudden change in brightness may be displayed.

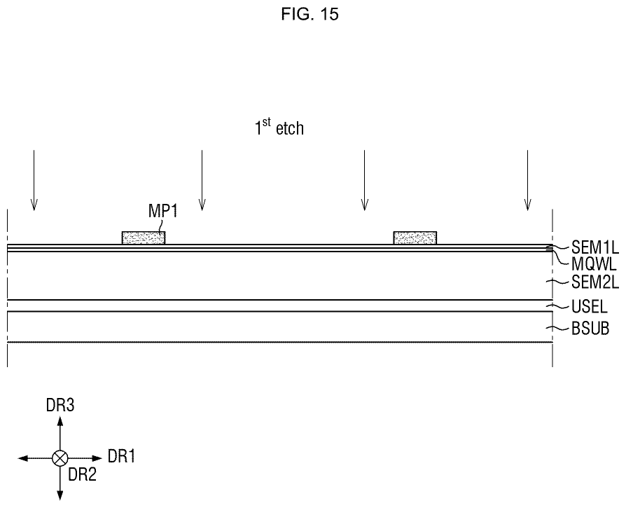

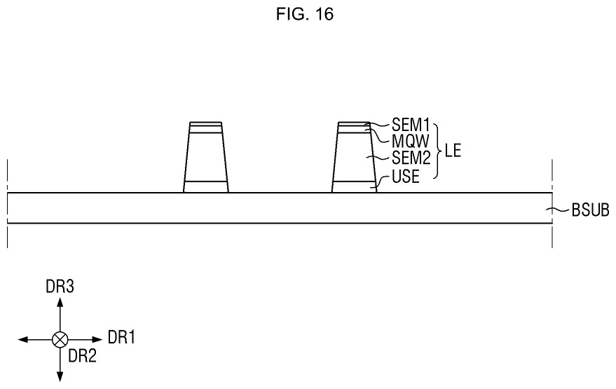

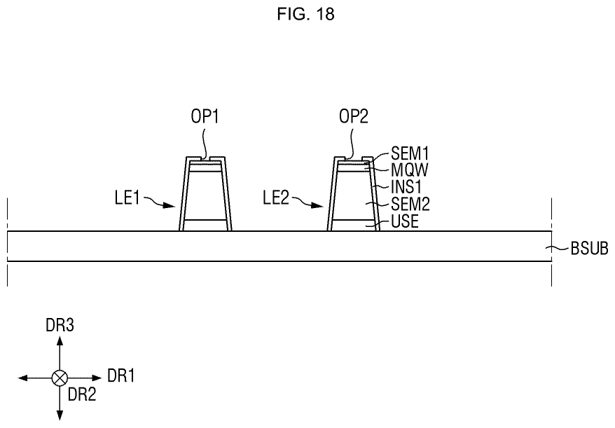

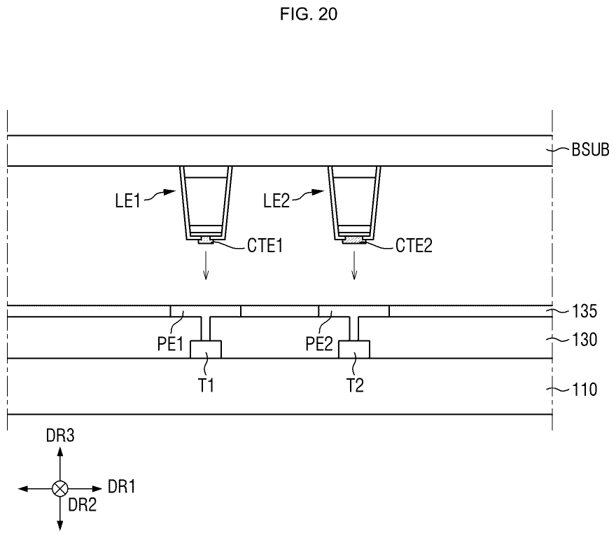

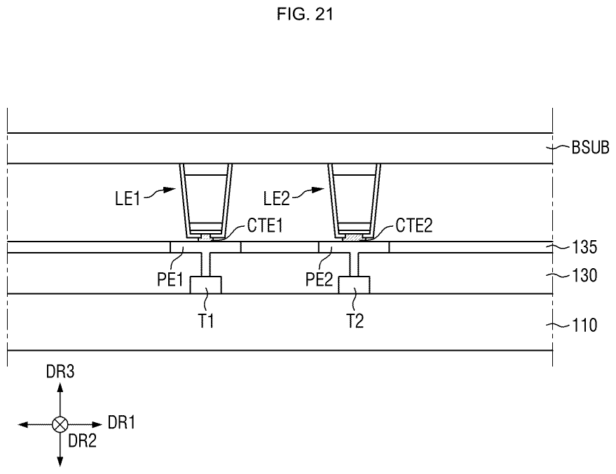

FIGS. 15 to 19 are drawings illustrating a manufacturing method of the light emitting element array according to one or more embodiments. FIGS. 20 and 21 are drawings illustrating a method of transferring the light emitting element array to a display board.

FIGS. 15 to 19 illustrate the structure of the light emitting element array according to the manufacturing sequence of the light emitting element array as cross-sectional views, respectively. These may correspond to the cross-sectional view of FIG. 2. In addition, the first light emitting element LE1 and the second light emitting element LE2 of the display device 10 are mainly shown.

Specifically, the base substrate BSUB is prepared. The base substrate BSUB may be a sapphire substrate Al₂O₃ and/or a silicon wafer including silicon. However, it is not limited thereto, and in one or more embodiments, a case where the base substrate BSUB is a sapphire substrate will be described as an example.

A plurality of semiconductor material layers USEL, SEM2L, MQWL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), and/or the like, and in one or more embodiments, may be formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group such as a methyl and/or ethyl group. For example, it may be a compound such as trimethyl gallium (Ga(CH₃)₃), trimethyl aluminum (Al(CH₃)₃), triethyl phosphate ((C₂H₅)₃PO₄) but are not limited thereto.

Specifically, a third semiconductor material layer USEL is formed on the base substrate BSUB. While the drawings illustrate the third semiconductor material layer USEL being further stacked, it is not limited to this, and a plurality of layers may be formed. The third semiconductor material layer USEL may be disposed to reduce a lattice constant difference between a second semiconductor material layer SEM2L and the base substrate BSUB. For example, the third semiconductor material layer USEL may include an undoped semiconductor, which may be an n-type or p-type undoped material. In one or more embodiments, the third semiconductor material layer USEL may be at least one of undoped InAlGaN, GaN, AlGaN, InGaN, AlN, and/or InN but is not limited thereto.

The second semiconductor material layer SEM2L, the active material layer MQWL, and the first semiconductor material layer SEM1L are sequentially formed on the third semiconductor material layer USEL by using the above-described method.

Then, the plurality of semiconductor material layers USEL, SEM2L, MQWL, and SEM1L are etched to form the plurality of light emitting elements LE1 and LE2.

Specifically, a plurality of first mask patterns MP1 are formed on the first semiconductor material layer SEM1L. The first mask pattern MP1 may be a hard mask including an inorganic material or a photoresist mask including an organic material. The first mask pattern MP1 prevents the lower plurality of semiconductor material layers USEL, SEM2L, MQWL, and SEM1L from being etched. Then, a portion of the plurality of semiconductor material layers is etched (1^{st} etch) using the plurality of first mask patterns MP1 as a mask to form the plurality of light emitting elements LE.

As shown in FIG. 15, on the base substrate BSUB, the plurality of semiconductor material layers USEL, SEM2L, MQWL, and/or SEM1L that are non-overlapping with the first mask pattern MP1 are etched and removed, and the portions that are not etched overlapping with the first mask pattern MP1 may be formed into the plurality of light emitting elements LE.

The semiconductor material layers may be etched by conventional methods. For example, the process of etching the semiconductor material layers may be dry etching, wet etching, reactive ion etching (RIE), deep reactive ion etching (DRIE), inductively coupled plasma reactive ion etching (ICP-RIE), and/or the like. In the case of dry etching methods, anisotropic etching is possible, which may be suitable for vertical etching. When utilizing the etching method described above, the etchant may be Cl₂ or O₂. However, it is not limited thereto.

The plurality of semiconductor material layers USEL, SEM2L, MQWL, and/or SEM1L overlapping the first mask pattern MP1 are not etched but are formed into the plurality of light emitting elements LE. Thus, the plurality of light emitting elements LE are formed including a third semiconductor layer USE, the second semiconductor layer SEM2, the active layer MQW, and the first semiconductor layer SEM1.

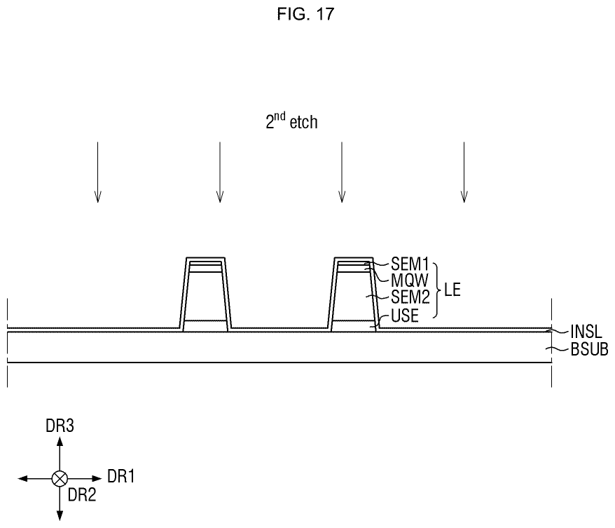

Referring to FIGS. 15 and 17, the first insulating layer INS1 is formed on the side surface of the light emitting element LE.

Specifically, the insulating material layer INSL is formed on the outer surfaces (e.g., outer peripheral or circumferential surfaces) of the plurality of light emitting elements LE. The insulating material layer INSL may be formed on the entire surface of the base substrate BSUB and may be formed not only on the light emitting element LE, but also on the upper surface of the base substrate BSUB exposed by the light emitting element LE.

Then, a 2^{nd} etch is performed to partially remove the insulating material layer INSL to form the first insulating layer INS1 having the opening on the upper surface of the light emitting element LE.

Specifically, the insulating material layer INSL may be partially removed to expose a portion of the upper surface of the first semiconductor layer SEM1 of the light emitting element LE. The process of partially removing the insulating material layer INSL to form the opening may be performed by a process such as an etch-back after anisotropic etching using a mask, followed by dry etching, but is not limited thereto.

In this case, the first opening OP1 of the first light emitting element LE1 and the second opening OP2 of the second light emitting element L2 may be formed differently from each other.

The second opening OP2 of the second light emitting element LE2 may be larger than the first opening OP1 of the first light emitting element LE1.

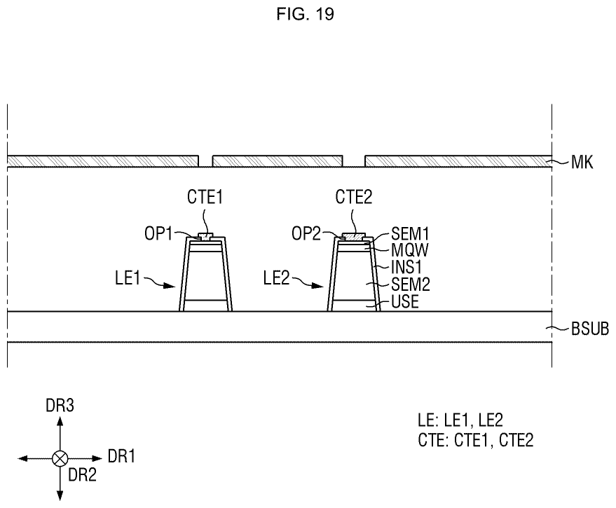

Next, referring to FIG. 19, the connection electrode CTE may be formed on the first light emitting element LE1 and the second light emitting element LE2 having the openings OP1 and OP2 formed through the mask process. The connection electrode CTE is formed on the first semiconductor layer SEM1 through the openings OP1 and OP2.

The connecting electrode CTE is formed by laminating a layer of electrode material on the base substrate BSUB and then forming photoresist on the openings OP1 and OP2 using the mask MK. Then, the electrode material layer in the area where the photoresist is not disposed is etched through an etching process. Subsequently, the photoresist may be removed to form within the openings OP1 and OP2. The connection electrode CTE is formed on the first semiconductor layer SEM1 through the openings OP1 and OP2.

Here, the mask may be a mask MK described with reference to FIGS. 7 to 9. The mask MK may include mask patterns MP having different sizes.

The connection electrode CTE may be formed on the openings OP1 and OP2 to protrude from the insulating layer INS1 in the third direction.

Next, referring to FIGS. 20 and 21, a first transfer film is bonded on the first substrate 110 and the plurality of light emitting elements LE are attached to the first and second pixel electrodes PE1 and PE2.

Specifically, the first substrate 110 having pixel circuits T1 and T2 is prepared.

The first substrate 110 may be an insulating substrate. The first substrate 110 may include a transparent material. For example, the first substrate 110 may include a transparent insulating material such as glass or quartz or the like. The first substrate 110 may be a rigid substrate. However, the first substrate 110 is not limited thereto and may include plastic such as polyimide, or the like, and may have flexible properties that allow it to be warped, bent, folded, or rolled.

In one or more embodiments, each of the pixel circuits T1 and T2 may be a thin film transistor including amorphous silicon, polysilicon, or an oxide semiconductor. In one or more embodiments, a plurality of signal lines (e.g., gate lines, data lines, power supply lines, etc.) for transmitting signals to the pixel circuits T1 and T2 may be further disposed on the first substrate 110.

Each of the pixel circuits T1 and T2 may include a semiconductor layer, a gate electrode, a source electrode, and a drain electrode. Specifically, the semiconductor layer may form a channel of each of the switching elements T1, T2, and T3. The semiconductor layer may include amorphous silicon, polycrystalline silicon, or an oxide semiconductor. The gate electrode may include a conductive material. The gate electrode may include a metal oxide such as ITO, IZO, ITZO, and/or In₂O₃, or a metal such as copper (Cu), titanium (Ti), aluminum (Al), molybdenum (Mo), tantalum (Ta), calcium (Ca), chromium (Cr), magnesium (Mg), and/or nickel (Ni). The source electrode and the drain electrode may be in contact with the semiconductor layer, and may include metal oxides such as ITO, IZO, ITZO, In₂O₃, and/or metals such as copper (Cu), titanium (Ti), aluminum (Al), molybdenum (Mo), tantalum (Ta), calcium (Ca), chromium (Cr), magnesium (Mg), and/or nickel (Ni).

A first planarization layer 130 may be disposed on each of the pixel circuits T1 and T2. The first planarization layer 130 may include an organic material. For example, the first planarization layer 130 may include an acrylic-based resin, an epoxy-based resin, an imide-based resin, an ester-based resin, and/or the like. In one or more embodiments, the first planarization layer 130 may include a positive photosensitive material or a negative photosensitive material.

The pixel electrodes PE1 and PE2 may be disposed on the first planarization layer 130. The pixel electrodes PE1 and PE2 are disposed to correspond to each of the pixel circuits T1 and T2 and may be electrically connected to them. The pixel electrodes PE1 and PE2 may contact the pixel circuits T1 and T2 through contact holes penetrating the first planarization layer 130.

A second planarization layer 135 may be disposed on the first planarization layer 130 in a section on which the pixel electrodes PE1 and PE2 are not disposed. The second planarization layer 135 flattens the level difference between the pixel electrodes PE1 and PE2 and may include the same material as the first planarization layer 130 described above.

Next, the base substrate BSUB is aligned on the first substrate 110. At this time, the connection electrode CTE of the light emitting element LE is aligned on the pixel electrodes PE1 and PE2 formed on the base substrate BSUB to face the substrate 110.

Subsequently, the first substrate 110 and the base substrate BSUB are bonded together. Specifically, the connection electrode CTE of the light emitting element LE formed on the base substrate BSUB is brought into contact with the pixel electrodes PE1 and PE2 of the substrate 110. At this time, the connection electrode CTE of the light emitting element LE is in contact with the pixel electrodes PE1 and PE2. Then, the first substrate 110 and the base substrate BSUB are bonded by melting and bonding the connection electrode CTE of the light emitting element LE and the pixel electrodes PE1 and PE2. The plurality of light emitting elements LE are bonded to the upper surfaces of the pixel electrodes PE1 and PE2.

The melting bonding may be performed by irradiating a laser onto the pixel electrodes PE1 and PE2 on the base substrate BSUB. The laser-irradiated pixel electrodes PE1 and PE2 may conduct high heat from the laser to bond the interface of the connecting electrode CTE of the light emitting element LE and the pixel electrodes PE1 and PE2. In particular, the pixel electrodes PE1 and PE2 may include copper (Cu) having excellent heat conduction and may have excellent adhesive properties with the connection electrode CTE of the light emitting element LE. The source of the laser used for the fusion bonding may be a YAG.

Next, the light emitting elements LE are separated from the base substrate BSUB by irradiating a 1^{st} laser to the base substrate BSUB. The base substrate BSUB is separated from each third semiconductor layer USE of the plurality of light emitting elements LE.

The process of separating the base substrate BSUB may be separated by a laser lift off (LLO) process. The laser lift-off process uses a laser, and a KrF excimer laser (248 nm wavelength) may be used as a source. The energy density of the excimer laser is irradiated in the range of about 550 mJ/cm² to 950 mJ/cm², and the incident area may be in the range of 50×50 μm² to 1×1 1 cm² but is not limited thereto. As the laser is irradiated to the base substrate BSUB, the base substrate BSUB may be separated from the light emitting element LE.

Thereafter, the third semiconductor layer USE may be removed by ashing. The third semiconductor layer USE may be partially left behind.

Although the present disclosure exemplifies that the light emitting element formed on the base substrate BSUB is bonded to the first substrate 110, it may be stretched using a stretched substrate.

The stretchable substrate may include a stretchable material. The stretchable material may include, for example, polyolefine, polyvinyl chloride (PVC), elastomeric silicone, elastomeric polyurethane, elastomeric polyisoprene, and/or the like. By transferring the light emitting elements LE onto such the stretchable substrate and then stretching it, the space between the light emitting elements LE may be adjusted as desired.

However, the aspects of the present disclosure are not restricted to the one set forth herein. The above and other aspects of the present disclosure will become more apparent to one of ordinary skill in the art to which the present disclosure pertains by referencing the claims, with functional equivalents thereof to be included therein.

What is claimed is:

1. A light emitting element array comprising:
a base substrate;
a plurality of light emitting elements on the base substrate;
an insulating layer on side surfaces and one surface of each of the plurality of the light emitting elements and having an opening on the one surface; and
a plurality of connection electrodes, each of the connection electrodes being at the opening in the one surface of the insulating layer of a corresponding one of the plurality of light emitting elements,
wherein the connection electrodes of neighboring light emitting elements of the plurality of light emitting elements have a different sizes, and
wherein connection electrodes of the plurality of light emitting elements are arranged on the base substrate in a repeating pattern.

2. The light emitting element array of claim 1, wherein a diameter of the opening in the insulating layer is proportional to a diameter of a corresponding one of the connection electrodes.

3. The light emitting element array of claim 1, wherein the plurality of light emitting elements comprises a first light emitting element and a second light emitting element adjacent to the first light emitting element, and
wherein a diameter of the connection electrode of the first light emitting element is smaller than a diameter of the connection electrode of the second light emitting element.

4. The light emitting element array of claim 3, wherein a diameter of a first opening in the insulating layer of the first light emitting element is smaller than a diameter of a second opening of the insulating layer of the second light emitting element.

5. The light emitting element array of claim 3, wherein the diameter of the connection electrode of the first light emitting element is different from diameters of the connection electrodes of light emitting elements of the plurality of light emitting elements located at an upper side, a lower side, a left side, and a right side of the first light emitting element.

6. The light emitting element array of claim 4, wherein the diameter of the first opening in the insulating layer of the first light emitting element is smaller than diameters of the openings in the insulating layers of the light emitting elements of the plurality of light emitting elements located at an upper side, a lower side, a left side, and a right side of the first light emitting element.

7. The light emitting element array of claim 2, wherein diameters of the connection electrodes of the plurality of light emitting elements in the light emitting element array gradually increase or decrease in a first direction and a second direction.

8. The light emitting element array of claim 2, wherein the base substrate is a sapphire substrate (Al₂O₃) or a silicon wafer comprising silicon.

9. A mask comprising:
a mask sheet on the base substrate when manufacturing the connection electrode of claim 1; and
a plurality of mask patterns in the mask sheet, having a light transmittance different from that of the mask sheet, and corresponding to connection electrodes on the base substrate,
wherein the plurality of mask patterns are regular polygonal patterns over the mask sheet, and
wherein the plurality of mask patterns have different sizes from neighboring mask patterns.

10. The mask of claim 9, wherein the plurality of mask patterns comprises a first pattern and a second pattern adjacent to the first pattern, wherein the first pattern is smaller than the second pattern.

11. The mask of claim 10, wherein the first pattern has a different size from patterns located at an upper side, a lower side, a left side, and a right side of the first pattern.

12. The mask of claim 10, wherein a size of the plurality of mask patterns decreases from a center to a side.

13. The mask of claim 10, wherein the plurality of mask patterns are light-transmitting areas, and an outer portion of the mask sheet where the plurality of mask patterns are not located is a light-blocking area.

14. A method of manufacturing a light emitting element comprising:
forming a plurality of semiconductor material layers on a base substrate;
etching the plurality of semiconductor material layers to form a plurality of light emitting elements;
forming an insulating layer around sides and one end of each of the plurality of light emitting elements;
forming an opening in the insulating layer of the one end of each of the plurality of light emitting elements; and
forming a connection electrode using a mask at the one end of each of the plurality of light emitting elements having the opening,
wherein the mask comprises a plurality of mask patterns corresponding to connection electrodes of the plurality of light emitting elements, and
wherein the plurality of mask patterns have polygonal shapes and has different sizes from neighboring mask patterns.

15. The method of claim 14, wherein the plurality of mask patterns comprises a first pattern and a second pattern adjacent to the first pattern, and wherein the first pattern is smaller than the second pattern.

16. The method of claim 15, wherein the first pattern has a different size from patterns located at an upper side, a lower side, a left side, and a right side of the first pattern.

17. The method of claim 14, wherein a size of the plurality of mask patterns decreases from a center to a side.

18. The method of claim 14, wherein a diameter of the opening in the insulating layer of is proportional to a diameter of the connection electrode in each of the plurality of light emitting elements.

19. The method of claim 18, wherein connection electrodes formed by the plurality of mask patterns have different sizes from connection electrodes of adjacent light emitting elements of the plurality of light emitting elements.

20. The method of claim 18, wherein diameters of the connection electrodes of the plurality of light emitting elements gradually increase or decrease in a first direction and a second direction.
